(19) United States
(12) Patent Application Publication
(10) Pub. No.: US 2003/0127719 A1
(43) Pub. Date: Jul. 10, 2003

(54) Structure and process for packaging multi-chip

(75) Inventor: Charge Chang, TaiChung (TW)

Correspondence Address: BRUCE H. TROXELL, 5205 LEESBURG PIKE, SUITE 1404, FALLS CHURCH, VA, 22041, US

(73) Assignee: PICTA TECHNOLOGY, INC.

(21) Appl. No.: 10/036,525

(22) Filed: Jan. 7, 2002

(51) Int. Cl. H01L 23/02; H01L 21/48

(52) U.S. Cl. 257/685; 438/107; 438/109; 257/686

(57) ABSTRACT

The structure and process for packaging multi-chip, which includes: a substrate; a plurality of chips, locating above said substrate and each chip is conducted electrically with the substrate by wire-bonding; several adhesion layers, each locating between any two adjacent chips to make themselves as a sandwiched shape; and several spacers, each covered in each of the adhesion layers for supporting each of the chips. Wherein, there is no suspension zone between each chip for facilitating the control of the wire-binding and making wire-bonding more accurately for raising the yield of process effectively.

### BACKGROUND OF THE INVENTION

1. Field of the Invention

The invention relates to a structure and a process for packaging multi-chip, especially to a structure and a process for packaging multi-chip to stack at least two chips with same or different functions within one package, and there is no suspension zone between any two adjacent chips.

2. Background of the Invention

In the trend of current semiconductor manufacture, how to squeeze more logic circuit into smaller semiconductor package and lower down the cost relatively has become a topic, to which all the semiconductor businesses are devoting their efforts, so the research and competition relative to this field are thereby very aggressive. Except the research manner that keeps shrinking the size of the minimized element of the circuit designed on the chip, another kind of manner that may directly reach the multiplication of memory capacity for a semiconductor package is to squeeze at least two pieces of chips within one single package.

The most common packaging structure for multi-chip is the side-by-side structure for packaging multi-chip, which makes at least two chips arranged side by side to each other on the main arranging surfaces with a substrate. The connection of the chip and the substrate is achieved by wire-bonding. However, the shortcoming of this side-by-side structure for packaging multi-chip is that its packaging efficiency is too low, because the area of common substrate will be increased following the increase of the chips.

As shown in FIG. 1A, in which U.S. Pat. No. 5,323,060 disclosed a multi-chip stacked device that includes a first semiconductor chip 110 arranged on a substrate 120 and connected to the substrate 120 with electricity, and a second semiconductor chip 130 stacked on the first semiconductor chip 110 and connected to the substrate 120 with electricity. It is characterized in that a necessity clearance is provided for the loop of the bonding wire by arranging an adhesive layer 140 between two chips. The thickness of the adhesive layer 140 must be larger than the loop height of the bonding wire. That is, the distance between the front surface of the first semiconductor chip 110 and the top point of the loop of the wire 150 is large enough to prevent the second semiconductor chip 130 from touching the loop of the wire 150.

It is known that the wire bonding technology for forming wire interconnection between the chip pad and the substrate pad generally includes: a) processing ball bond on the chip pad, b) forming wire loop between the chip pad and the substrate pad, and c) stitching bond to the substrate pad to complete the connection of bonding wire. Generally, the loop height is about 10 to 15 mil. Although the wire bonding technique of prior arts may reduce the loop height to about 6 mil by adjusting the factors of wire loop, appearance and form, but this is the least loop height obtainable, because lower loop height might damage the wire and weaken its strength.

Therefore, in applying the wire bonding technique of prior arts, the thickness of the adhesive layer 140 must be larger than 8 mil for completely preventing the second semiconductor chip 130 from touching the loop of wire 150. Generally, the adhesive layer 140 is made of materials of epoxy or adhesive tape. However, to form a thickness of 8 mil for epoxy layer is very difficult. In addition, when an adhesive tape with thickness of 8 mil is applied, the cost of production will be increased greatly, and on the other hand, the CTE mismatch between the adhesive layer 140 and silicone chip will also seriously damage the reliability of the produced packaging structure.

Therefore, as shown in FIG. 1B, in which U.S. Pat. No. 6,005,778 disclosed another kind of multi-chip stacked device that includes a first semiconductor chip 110 arranged on a substrate 120 and electrically connected to the substrate 120, and a second semiconductor chip 130 stacked on the first semiconductor chip 110 and electrically connected to the substrate 120. The U.S. Pat. No. 6,005,778 is characterized in that arranging a spacer 160 between two chips provides a necessity clearance for the loop of the wire 150. In addition, the spacer 160 made of materials of conductive metal may also be served as a grounding surface for the semiconductor chip and provided for the arrangement of electric capacitance. Although the spacer 160 of the U.S. Pat. No. 6,005,778 has already solved the shortcoming of said adhesive layer 140 according U.S. Pat. No. 5,323,060, but a suspension zone will be generated with the spacer during the upper chip being stacked. When the upper chip is bonded with wire, this structure will be incurred difficulty during processing and displaced easily during wire bonding to influence its accuracy, lower down the yield of process, and further influence the competition ability.

### SUMMARY OF THE INVENTION

The main object of the invention is to provide a structure and process for packaging multi-chip to make the wire-bonding be controlled more easily.

The further object of the invention is to provide a structure and process for packaging multi-chip to make the wire-bonding be more accurately.

The still further object of the invention is to provide a structure and process for packaging multi-chip to effectively promote the yield of productivity.

To achieve above-mentioned objects, the invention provides a structure for packaging multi-chip, which includes: a substrate; a plurality of chips, locating above said substrate and each chip is conducted electrically with the substrate by wire-bonding; several adhesion layers, each locating between any two adjacent chips to make themselves as a sandwiched shape; and several spacers, each covered in each of the adhesion layers for supporting each of the chips.

Preferably, the process of the structure for packaging multi-chip includes following steps:

(a) adhering a first chip to a substrate;

(b) applying the first chip with wire-bonding for being electrically conducted with the substrate;

(c) adhering a spacer onto the first chip with a first adhesion layer, and the size of the spacer is smaller than that of the first chip;

(d) covering a second adhesion layer for adhering a second chip, wherein the spacer is covered within an adhesion layer formed between the first adhesion layer and the second adhesion layer, and the first chip, the adhesion layer, and the second chip are as a sandwiched shape;

(e) applying the second chip with wire-bonding for being electrically connected with the substrate.

Preferably, it may be repeated more times from “step c” through “step e” for completing the package of more chips.

### BRIEF DESCRIPTION OF THE DRAWINGS

FIG. 1A is an illustration for the structure for packaging semiconductor multi-chip according to the prior arts.

FIG. 1B is a further illustration for the structure for packaging semiconductor multi-chip according to the prior arts.

FIG. 2 is an illustration for the first preferable embodiment of the structure for packaging multi-chip according to the present invention.

FIG. 3A through FIG. 3F are the illustrations for the flow path of a preferable process embodiment for the first preferable embodiment for the structure for packaging multi-chip shown in FIG. 2.

FIG. 4 is an illustration for the second preferable embodiment of the structure for packaging multi-chip according to the present invention.

FIG. 5A is an illustration for a preferable embodiment for the first preferable embodiment according to the invention coupling to the outside.

FIG. 5B is an illustration for a further preferable embodiment for the first preferable embodiment according to the invention coupling to the outside.

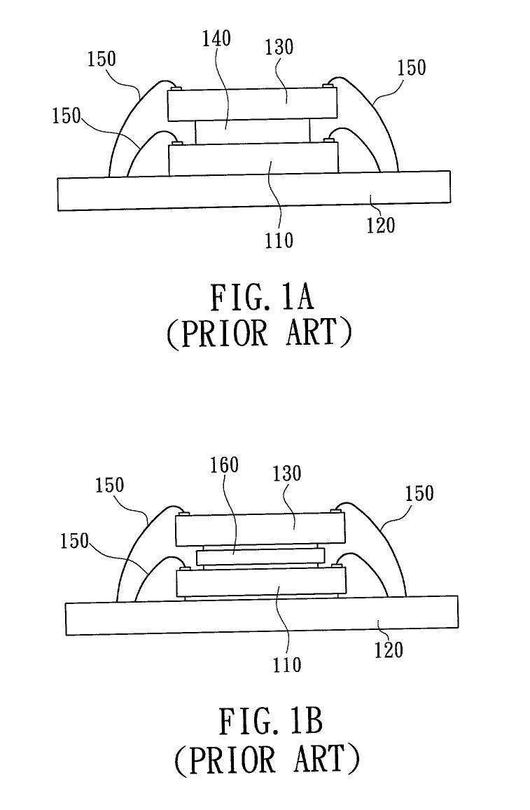

### DETAILED DESCRIPTION OF THE PREFERRED EMBODIMENTS

The invention relates to a structure and a process for packaging multi-chip to stack at least two chips with same or different functions within one package, and there is no suspension zone between two adjacent chips. A structure for packaging multi-chip according to the invention includes a substrate, plural chips located above the substrate and each conducted the substrate with electricity by the wire-bonding respectively, several adhesion layers located between two chips and sandwiched thereby, and several spacers covered within each adhesion layer for supporting each chip.

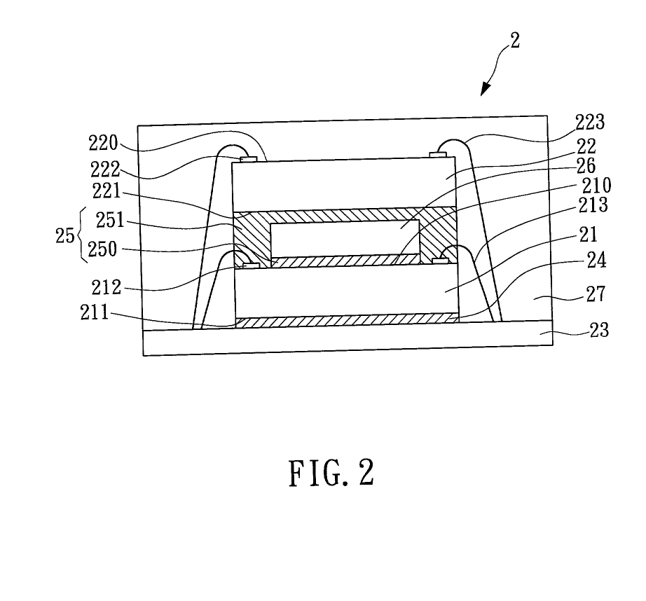

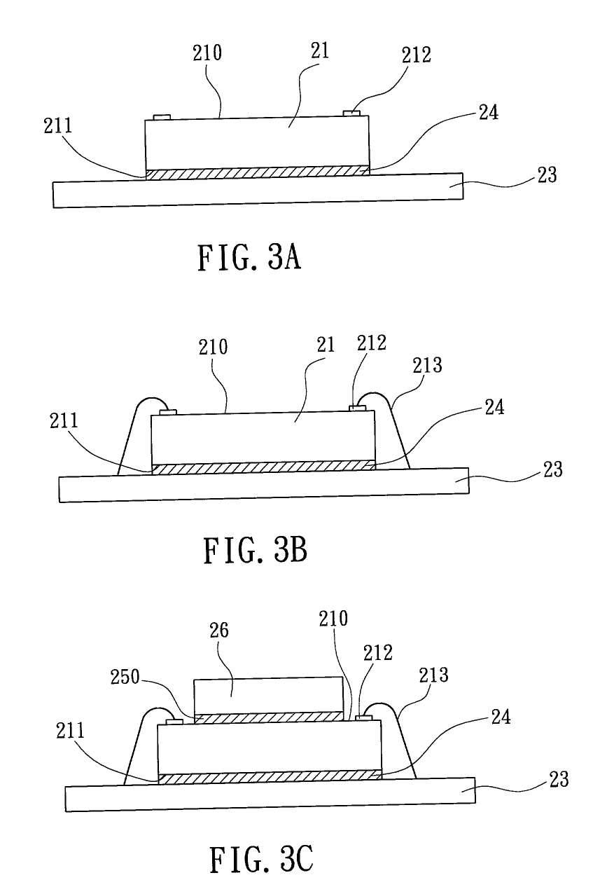

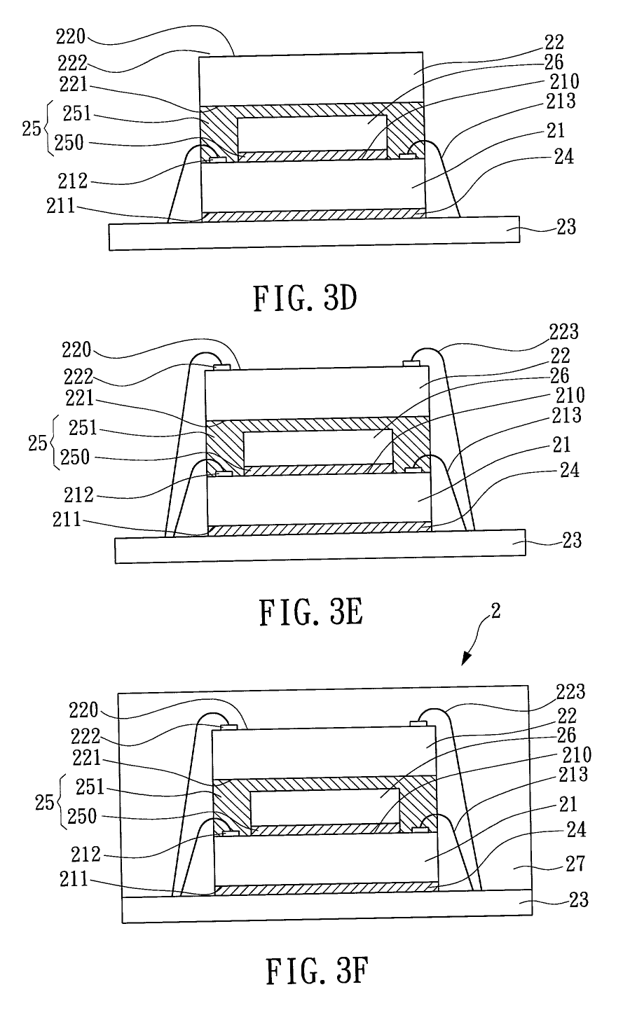

Please refer to FIG. 2, which is an illustration for the first preferable embodiment for the structure for packaging multi-chip according to the invention, while FIG. 3A through FIG. 3F show a preferable embodiment for the flow path of processing steps for the first preferable embodiment shown in FIG. 2.

In the first preferable embodiment shown in FIG. 2, the structure for packaging multi-chip 2 includes plural chips, a substrate 23, several adhesion layers, and several spacers. In this embodiment, the plural chips located above the substrates 23 include a first chip 21 and a second chip 22. The chips 21, 22 each has an active side 210, 220 and an inactive side 211, 221 respectively. The active sides 210, 220 each is belonged to one side surface of the chips 21, 22 respectively, on which the circuit is designed. Further, there are plural solder pads 212, 222 arranged at the predetermined positions on the active sides 210, 220 of the chips 21, 22 respectively for serving as interconnection interfaces between the circuits on the chips 21, 22 and the outside. In this preferable embodiment, the solder pads 212, 222 are the metal pads or Al pads so-called by the business.

The plural solder pads 212, 222 on the active side 210 of the first chip 21 and the active side 220 of the second chip 22 are electrically connected to the substrate 23 by the wires 213, 223, while the inactive side 211 of the first chip 21 is connected onto the substrate 23. In this preferable embodiment, the inactive side 211 of the first chip 21 is adhered onto the substrate 23 by the chip adhesion layer 24. The chip adhesion layer 24 may adopt the adhesive materials such as dual-sided adhesive tape, silver glue, or epoxy, etc.

The several adhesion layers located between each two adjacent chips are formed as sandwiched shape. In the present invention, the adhesion layer 25 includes a first adhesion layer 250 and a second adhesion layer 251. Wherein the first adhesion layer 250 is adapted for adhering the spacer 26, while the second adhesion layer 251 is adapted for stuffing the clearance position between the first chip 21 and the second chip 22 to make the second chip 22 compactly and smoothly adhered onto the second adhesion layer 251. In practice, both the first adhesion layer 250 and the second adhesion layer 251 also adopt the adhesive materials such as dual-sided adhesive tape, silver glue, and epoxy, etc, so they can be served as an entire adhesion layer 25, in which the spacer 26 is covered for supporting the second chip 22.

By the sandwiched structure shown as FIG. 2, because there is no clearance between the first chip 21 and the second chip 22, the packaging structure for multi-chip 2 according to the invention not only makes the wire-bonding controlled more easily but also makes it more accurately for promoting the yield of process effectively. The first chip 21 and the second chip 22 may be chips having different functions respectively. For, example, the first chip 21 may be a chip of logic circuit, while the second chip 22 is a chip of memory circuit. Thus, various chips with different functions may be included in one single IC for enhancing the design ability and application flexibility of an IC. Of course, those who are skilled in the semiconductor technology should have envisioned easily that both the first chip 21 and the second chip 22 are two chips having same function after referring aforementioned description.

In the embodiments hereinafter, the element bearing the same function as that of aforementioned element will be designated same number and name, and its function will not be repetitiously described herein any more.

Please refer to FIG. 3A through FIG. 3F, which show a preferable process step flow path embodiment for the multi-chip packaging structure 2 embodiment shown in FIG. 2, wherein the flow path embodiment includes following steps:

(a) Connect the inactive side 211 of a first chip 21 onto the substrate 23 by a chip adhesion layer 24.

(b) Make the solder pad 212 on the active side 210 of the first chip 21 coupled to the substrate 23 by the wire 213 to make the circuit on the first chip 21 be able to conduct electrically to the substrate 23, which further conducts electrically to the outside.

(c) Connect the spacer 26 onto the active side 210 of the first chip 21 with a first adhesion layer 250, and the size of the spacer 26 is smaller than that of the first chip 21 so that it won't crash down the wire 213.

(d) Cover a second adhesion layer 251, which covers the exposing part of the active side 210 of the first chip 21 and also covers the exposing parts of both the spacer 26 and the first adhesion layer 250 for connection the inactive side 221 of the second chip 22, wherein the first adhesion layer 250 and the second adhesion layer 251 form an adhesion layer 25, within which the spacer 26 is covered, and the first chip 21, the adhesion layer 25, and the second chip 22 are formed as a structure of sandwiched shape.

(e) By wire-bonding, make the solder pad 222 on the active side 220 of the second chip 22 be coupled to the substrate 23 through the wire 223 to make the circuit on the second chip 22 be able to connect electrically to the substrate 23 to complete the multi-chip packaging structure 2.

(f) Then, for molding process, cover the multi-chip packaging structure with encapsulation 27 for protection to complete the entire multi-chip packaging structure 2.

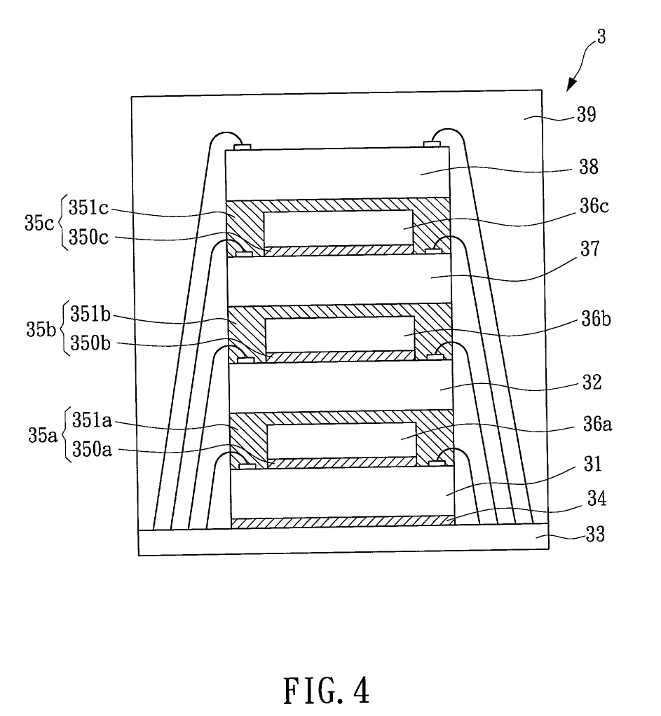

Please refer to FIG. 4, which is an illustration for the second preferable embodiment of the packaging structure for multi-chip according to the invention.

In the second preferable embodiment shown in FIG. 4, after the packaging structure for multi-chip 3 also connects the first chip 31 onto the substrate 33 by the chip adhesion layer 34, the circuit of the first chip 31 may be electrically conducted to the substrate 33 by the wire-bonding. Afterwards, repeating the “step c” through “step e” in the first embodiment may cover the spacer 36a with a adhesion layer 35a constituted by the first adhesion layer 350a and the second adhesion layer 351a and connect the second chip 32 by the adhesion layer 35a, cover the spacer 36b with a adhesion layer 35b constituted by the first adhesion layer 350b and the second adhesion layer 351b and connect the third chip 37 by the adhesion layer 35b, and cover the spacer 36c with a adhesion layer 35c constituted by the first adhesion layer 350c and the second adhesion layer 351c and connect the fourth chip 38 by the adhesion layer 35c. Finally, for molding process, the packaging structure for multi-chip is covered by the encapsulation 30 for protection to form a complete multi-chip packaging structure 3. Thereby, a package for further more chips may be completed and there is still no clearance between every chip. Therefore, it won't influence the control of wire bonding due to the package of further more chips. The accuracy of wire bonding won't be lowered and the yield and speed of process may be raised effectively. Such kinds of advantages are numberless and not repeated herein any more.

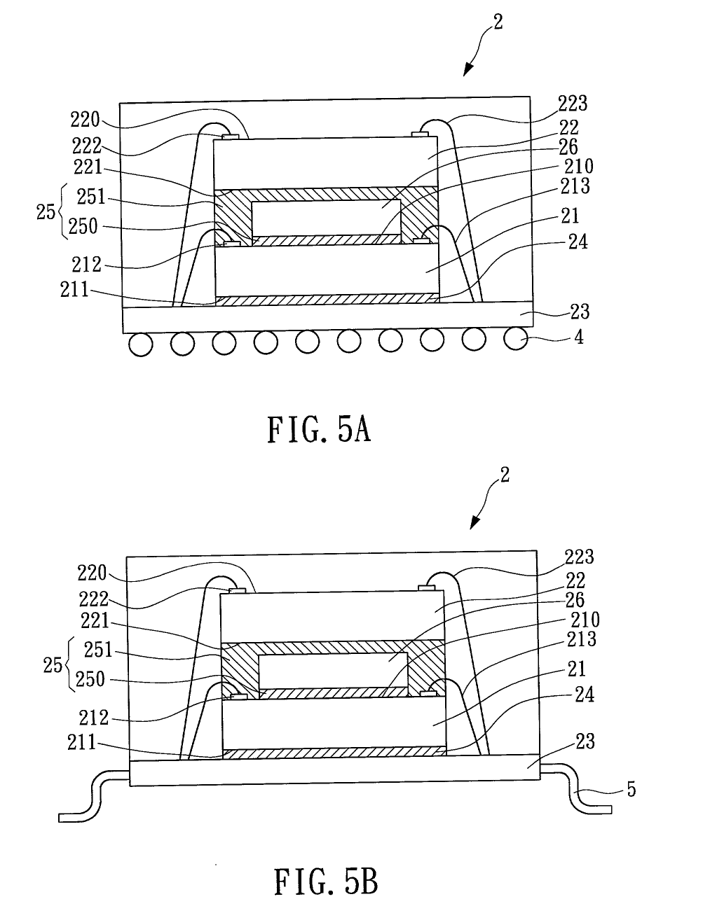

As shown in FIG. 5A, which is a preferable embodiment for coupling the first preferable embodiment of the invention to the outside. Wherein, plural solder balls 4 may be arranged on the substrate 23 of the packaging structure for multi-chip 2 and it is possible to apply said solder balls 4 for coupling other circuit board to complete electric connection. Furthermore, as shown in FIG. 5B, which is a further preferable embodiment for coupling the first preferable embodiment of the invention to the outside. Wherein, it is possible to couple with other circuit board by the manner of inserting lead 5 into the substrate of the packaging structure for multi-chip 2 to complete electric connection. Of, course, after referring aforementioned description, any one who is skilled in the semiconductor technology should conceive easily that above-mentioned manner or other common manner might also be adopted for coupling the second preferable embodiment of the invention to the outside.

In summary, the structure and the process for packaging multi-chip according to the invention not only make the wire-bonding be controlled more easily but also makes the wire-bonding more accurate for raising the yield of process effectively. Further, the structure and the process for packaging multi-chip may be selectively adapted to include various chips with different functions in one single IC simultaneously (or plural chips with same function). It is possible to greatly increase the design ability and application flexibility for an IC, reduce its total volume and size, make the entire structure and process very easy, and finally lower down the manufacturing cost.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A structure for packaging multi-chip, including:
a substrate;
a plurality of chips, locating above said substrate and each chip conducted electrically with the substrate by wire-bonding;
several adhesion layers, each locating between any two adjacent chips to make themselves as a sandwiched shape; and
several spacers, each covered in each of the adhesion layers for supporting each of the chips.

2. The structure for packaging multi-chip as recited in claim 1, wherein each chip further includes plural solder pads.

3. The structure for packaging multi-chip as recited in claim 2, wherein the solder pads are Al pads.

4. The structure for packaging multi-chip as recited in claim 1, wherein the structure for packaging multi-chip is covered by an encapsulation for protecting the structure for packaging multi-chip.

5. The structure for packaging multi-chip as recited in claim 1, wherein arranged plural solder balls are on the substrate and the structure for packaging multi-chip is connected with a circuit board by the solder balls.

6. The structure for packaging multi-chip as recited in claim 1, wherein the structure for packaging multi-chip is connected with a circuit board by inserting lead into the substrate.

7. A process for multi-chip packaging structure as claim 1, comprising the steps of:
a) adhering a first chip to a substrate;
b) applying the first chip with wire-bonding for being electrically conducted with the substrate;
c) adhering a spacer onto the first chip with a first adhesion layer, and the size of the spacer is smaller than that of the first chip;
d) covering a second adhesion layer for adhering a second chip, wherein the spacer is covered within an adhesion layer formed between the first adhesion layer and the second adhesion layer, and the first chip, the adhesion layer, and the second chip are as a sandwiched shape;
e) applying the second chip with wire-bonding for being electrically connected with the substrate.

8. The process for multi-chip packaging structure as recited in claim 7, there is a further step after “step e”, repeating “step c” through “step e” for completing the package of further more chips.

9. The process for multi-chip packaging structure as recited in claim 7, further comprising, after “step e”, the step of:
f) Covering the multi-chip packaging structure with an encapsulation for protecting the multi-chip packaging structure.

10. The process for multi-chip packaging structure as recited in claim 8, further comprising, after “step e”, the step of:
f) Covering the multi-chip packaging structure with an encapsulation for protecting the multi-chip packaging structure.

11. The process for multi-chip packaging structure as recited in claim 7, wherein the first chip and the second chip are the chips with different functions.

12. The process for multi-chip packaging structure as recited in claim 7, wherein the first chip and the second chip are the chips with same function.
